(19) United States
(12) Patent Application Publication
(10) Pub. No.: US 2024/0098935 A1
(43) Pub. Date: Mar. 21, 2024

(54) COMPLIANT COUNTER-FLOW COLD PLATE

(71) Applicant: INTERNATIONAL BUSINESS MACHINES CORPORATION, ARMONK, NY (US)

(72) Inventor: MARK D. SCHULTZ, OSSINING, NY (US)

(21) Appl. No.: 18/358,232

(22) Filed: Jul. 25, 2023

Related U.S. Application Data
(60) Provisional application No. 63/408,731, filed on Sep. 21, 2022.

(51) Int. Cl. H05K 7/20; F28F 13/08

(52) U.S. Cl. CPC H05K 7/20272; F28F 13/08; H05K 7/20254

(57) ABSTRACT

A compliant counter-flow cold plate for component cooling includes a manifold body configured to be thermally coupled to a heat generating component and configured to be compliant under a distributed pressure load, and a plurality of expanding channels within the manifold body. At least one of the plurality of expanding channels extends from an inlet portion of the manifold body to an outlet portion of the manifold body.

### BACKGROUND

### Field of the Invention

The field of the invention is data processing, or, more specifically, methods, apparatus, and products for a compliant counter-flow cold plate.

### Description of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago.

With the increase in performance of computer system hardware, the need to remove heat from heat generating components such as processors, for example central processing units (CPUs) and graphics processing units (GPUs), is becoming increasingly more important. Thermal cooling solutions are usually employed to assist in heat removal from processors. Often one or more cooling elements are thermally coupled to the heat generating component, such as processor cores, to dissipate heat generated by the component. Such cooling elements include, for example, cold plates, heat sinks, fluid cooling systems (e.g., water cooling systems), vapor chambers, heat pipes, fans, and the like to conduct heat to dissipate the heat out of the computing device. However, existing solutions may not adequately cool components of a computing system.

### SUMMARY

In an embodiment, an apparatus for a compliant counter-flow cold plate for component cooling includes a manifold body configured to be thermally coupled to a heat generating component, and a plurality of expanding channels within the manifold body. The manifold body is configured to be compliant under a distributed pressure load. At least one of the expanding channels extends from an inlet portion of the manifold body to an outlet portion of the manifold body.

In an embodiment, a first cross-section the at least one expanding channel is smaller at the inlet portion of the manifold body than a second cross-sectional area at the outlet portion of the manifold body. In an embodiment, at least one pin structure is disposed within the at least one expanding channel.

In an embodiment, the plurality of expanding channels further includes a first expanding channel having a first flow direction and a second expanding channel having a second flow direction, the first flow direction being counter to the second flow direction.

In an embodiment, the outlet portion of the manifold body includes a return plenum in a center portion of the manifold body. In an embodiment, the return plenum includes a matrix of heat dissipating structures. In an embodiment, the return plenum includes a matrix of load carrying structures. In an embodiment, the outlet portion of the manifold body further includes a manifold outlet coupled to the return plenum.

In an embodiment, the at least one expanding channel includes at least two sidewall portions arranged in a zig-zag configuration. In an embodiment, the manifold body includes a first manifold body portion coupled to a second manifold body portion. In an embodiment, the manifold body is formed of a plurality of stacked layers.

In an embodiment, the inlet portion comprises an inlet channel coupled to an inlet orifice of each of the expanding channels. In an embodiment, the inlet channel is arranged in a loop configuration within the manifold body.

In an embodiment, the outlet portion comprises an outlet channel coupled to one or more outlet orifices of each of the expanding channels. In an embodiment, the outlet channel is arranged in a loop configuration within the manifold body.

In an embodiment, an apparatus for a compliant counter-flow cold plate for component cooling includes a manifold body configured to be thermally coupled to a heat generating component; and a plurality of expanding channels within the manifold body. At least one of the plurality of expanding channels extends from an inlet portion of the manifold body to an outlet portion of the manifold body. The apparatus further includes at least one pin structure disposed within the at least one expanding channel. The plurality of expanding channels further includes a first expanding channel having a first flow direction and a second expanding channel having a second flow direction, the first flow direction being counter to the second flow direction.

In an embodiment, a first cross-section area of the at least one expanding channel is smaller at the inlet portion of the manifold body than a second cross-sectional area at the outlet portion of the manifold body.

An embodiment of a method for compliant counter-flow cooling for a component includes providing a manifold body configured to be thermally coupled to a heat generating component, and forming a plurality of expanding channels within the manifold body. The manifold body is configured to be compliant under a distributed pressure load. At least one of the plurality of expanding channels extends from an inlet portion of the manifold body to an outlet portion of the manifold body.

In an embodiment, a first cross-section area of the at least one expanding channel is smaller at the inlet portion of the manifold body than a second cross-sectional area at the outlet portion of the manifold body.

In an embodiment, the method further includes forming at least one pin structure disposed within each of the plurality of expanding channels. In an embodiment, the plurality of expanding channels further includes a first expanding channel having a first flow direction and a second expanding channel having a second flow direction, the first flow direction being counter to the second flow direction.

In an embodiment, the outlet portion of the manifold body includes a return plenum in a center portion of the manifold body.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1A sets forth a diagram of a component cooling system utilizing a compliant counter-flow cold plate according to embodiments of the present invention.

FIG. 1B sets forth a diagram of a component cooling system utilizing a rigid heat sink instead of a compliant counter-flow cold plate.

FIG. 2 illustrates a perspective view of a compliant counter-flow cold plate according to embodiments of the present invention.

FIG. 3 illustrates another perspective view of the compliant counter-flow cold plate of FIG. 2.

FIG. 4 shows a detail view of a portion of the expanding channels of the compliant counter-flow cold plate of FIG. 2.

FIG. 5 shows a detail view of a portion of the compliant counter-flow cold plate of FIG. 2.

FIG. 6 shows a detail view of the manifold outlet of the compliant counter-flow cold plate of FIG. 2.

FIG. 7 shows a detail view of the manifold inlet of the compliant counter-flow cold plate of FIG. 2.

FIG. 8 illustrates a perspective view of a compliant counter-flow cold plate according to another embodiment of the present invention.

FIG. 9 illustrates a perspective cut-away side view of a portion of a first side of the compliant counter-flow cold plate of FIG. 8.

FIG. 10 illustrates another perspective cut-away view of a portion of the compliant counter-flow cold plate of FIG. 8.

FIG. 11 illustrates a cut-away side view of a portion of the compliant counter-flow cold plate of FIG. 8.

FIG. 12 illustrates another perspective cut-away side view of a portion of the compliant counter-flow cold plate of FIG. 8.

FIG. 13 illustrates a perspective view of a first layer of the manifold body of FIG. 8.

FIG. 14 illustrates a perspective view of a second layer of the manifold body of FIG. 8.

FIG. 15 illustrates a perspective view of a third layer of the manifold body of FIG. 8.

FIG. 16 illustrates another perspective view of the inlet and outlet structures for the centrally located return plenum of the manifold body of FIG. 8.

FIG. 17 illustrates still another perspective view of the inlet and outlet structures for the centrally located return plenum of the manifold body of FIG. 8.

FIG. 18 sets forth a flow chart illustrating an exemplary method for compliant counter-flow cooling for a component according to embodiments of the present invention.

### DETAILED DESCRIPTION

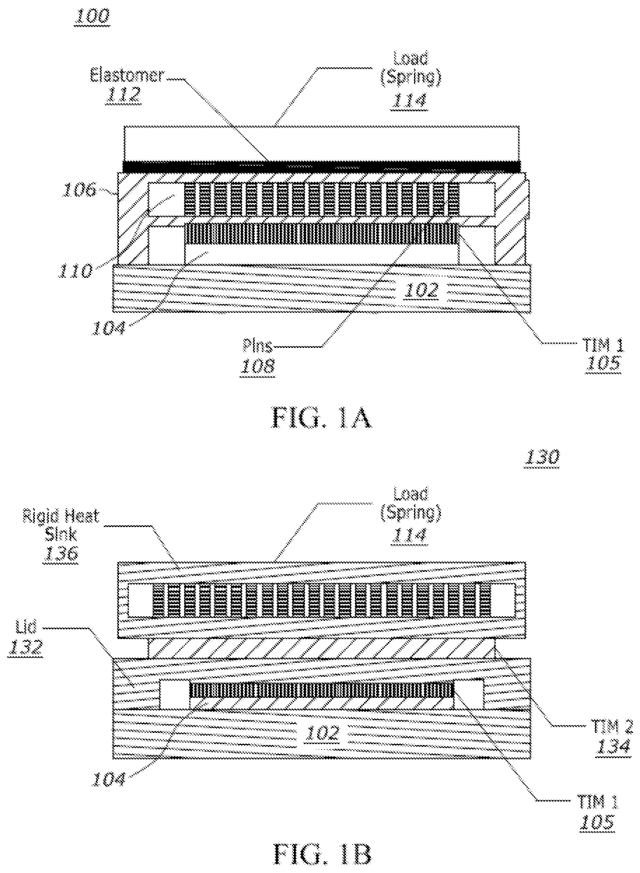

Exemplary methods, apparatus, and products for a compliant counter-flow cold plate for component cooling in accordance with the present invention are described with reference to the accompanying drawings, beginning with FIG. 1A. Compliant cold plate technology has been utilized as a thermal cooling solution for large die packages such as large Single Chip Modules (SCMs), Dual Chip modules (DCMs), and Multi-Chip Modules (MCMs). Compliant cold plates include a compressible layer that drives the compliant cold plate to conform to dimensional differences between the cold plate and the heat generating component being cooled. Compliance is important for system reliability and consistent thermal performance across large die (e.g., SCM, DCM, and MCM) packages. Previous solutions in this space have utilized single phase liquid as a heat transport fluid, generally water with additives to prevent corrosion and/or freezing). However, in the event of water leaks, such solutions present a risk to systems incorporating such cold plates due to the electrical conductivity of the heat transport fluid. Other single-phase fluids without this risk come with a generally unacceptable reduction in thermal performance.

An alternative to single phase water cooling is two phase flow boiling in which certain refrigerants can be used in a pumped or “thermosyphon” mode to effectively cool electronics. Thermosyphon is a method of passive heat exchange based on natural convection in which a fluid is circulated without the need for a mechanical pump. Radially expanding channels with properly designed inlet orifices have been demonstrated to show excellent cooling performance in an embedded configuration. Expanding counter-flow channels have also been proposed, but manifolding such channels in an embedded configuration is problematic. Such channels are superior to radial configurations for DCM type implementations where a radial solution would exhibit large differences in channel length making flow and pressure drop control difficult. Cold plates with expanding counter-flow channels have been proposed, but the existing art presents no solutions compatible with the low base thermal resistance of an optimum compliant solution and/or cannot support the base refrigerant pressures without deforming when implemented in a compliant mode.

One or more embodiments described herein provide for a compliant pumped or “thermosyphon” expanding channel cold plate that is manufacturable within the constraints of processes demonstrated for single phase compliant cold plates. One or more embodiments provide for a cold plate having an expanding counter-flow channel design which implements links or pin structures between a top portion and bottom portion within the channel. In one or more embodiments, the links or pin structures within each expanding channel may serve multiple purposes include providing additional heat transfer surface area, thermally coupling the top of the channel to the bottom of the channel, allowing heat transfer from the top of the channel as well as allowing for additional heat transfer layers above the channel as these links can move heat up into the additional heat transfer layers. In one or more embodiments, the links or pin structures disturb the flow of fluid through the channels to break up what would otherwise be performance reducing boundary layers.

In a particular embodiment, the channels are formed in a manifold body formed of two mating halves of material such as copper. During manufacture, links and guiding walls are formed when the material surrounding them is removed to form the channels. In a particular embodiment, an inlet orifice is formed as a result of material removal at the inlet in either or both halves of the manifold body to form an active heat transfer layer. In some embodiments, pairs of the halves are stacked on each other for additional heat transfer surface area. Accordingly, various embodiments provide for a cold plate having a combination of compliance, high thermal performance, and resistance to high refrigerant saturation pressures that is not available with existing solutions.

In various embodiments, a cold plate is manufactured using a copper diffusion bonding process, a silver-copper thermo-compression process, or an additive plating process in which the channels are defined with a photoresist or equivalent. While various embodiments are shown as using channels formed into both a top and a bottom half of a manifold body, in other embodiments the channels are formed in only one half of the manifold body. The formation of channels in both the top and bottom portions of the manifold allow for lower pressure drop and more surface area for a given channel depth constraint. In various embodiments, channel depth is a function of minimum feature (e.g., link) size. Smaller links allow for shallower depth and provide more surface area due to higher density than larger links.

In particular embodiments, inlet orifices of the manifold body are nominally 300 micrometers wide by 100 micrometers deep and varying length. The pressure drop across the inlet orifice is adjusted by varying length, width and/or depth. In particular embodiments, a cross-section at the outlet orifice between links is nominally 3 mm wide by 200 micrometers thick to result in a nominal flow cross-section increase of 20 times. This is well suited for assuring flow stability in each section regardless of input power levels relative to neighboring sections.

Particular embodiments provide for an active area that addresses two neighboring chips of a dual chip module. In an embodiment, both the inlets and outlets are linked (e.g., manifolded) together around the perimeter of the active area. In the embodiment, the outlet manifold flow cross-section is much larger than that of the inlet to allow for a very thin, very flexible active area which can be backed by a distributed load (e.g., an elastomer) utilized to drive compliance with the component being cooled. In another embodiment, substantially an entire area above the active cooling area is utilized as an outlet manifold to mitigate risk of outlet pressure variations driven by manifold flow pressure drop. In such an embodiment, the outlet manifold also serves as additional heat transfer area by including local links from layer to layer. In one or more embodiments, the manifolding is configured to maintain cold plate geometry when the cold plate is exposed to a relatively high refrigerant saturation pressure.

FIG. 1A sets forth a diagram of a component cooling system 100 utilizing a compliant counter-flow cold plate according to embodiments of the present invention. The component cooling system of FIG. 1A includes a substrate 102 having an integrated circuit (IC) die 104 mounted thereto. The IC die 104 includes a first thermal interface material (TIM) 105 disposed between a compliant counter-flow cold plate 106 as described herein with respect to various embodiments. As illustrated in FIG. 1A, the compliant counter-flow cold plate 106 is directly attached to the IC die 104 via the first TIM 105. The compliant counter-flow cold plate 106 includes a number of pin structures 108 disposed within a number expanding channels 110. An elastomer 112 is disposed on a top surface of the compliant counter-flow cold plate 106 and a load 114 is configured to apply pressure to the elastomer 112. In a particular embodiment, the load 114 includes one or more springs. The compliance of the compliant counter-flow cold plate 106 greatly reduces stress on the first TIM 105 and significantly improves performance of the first TIM 105 due to a uniform gap and loading. Although not illustrated in FIG. 1A, the component cooling system includes an inlet and outlet to circulate a fluid through the expanding channels 110.

FIG. 1B sets forth a diagram of a component cooling system 130 utilizing a rigid heat sink instead of a compliant counter-flow cold plate. In the component cooling system 130 of FIG. 1B, the IC die 104 is mounted to the substrate and a lid 132 is coupled to the IC die 104 via the first TIM 105. A liquid cooled rigid heat sink 136 is thermally coupled to the lid 132 via a second TIM 134. The load 114, which may include one or more springs, is applied to a top surface of the liquid cooled rigid heat sink 136. Since the component cooling system 130 lacks the compliant counter-flow cold plate 106 of FIG. 1A, the performance of the first TIM 105 is reduced. Overall system thermal performance is also reduced due to the TIM2 and lid that the heat must go through.

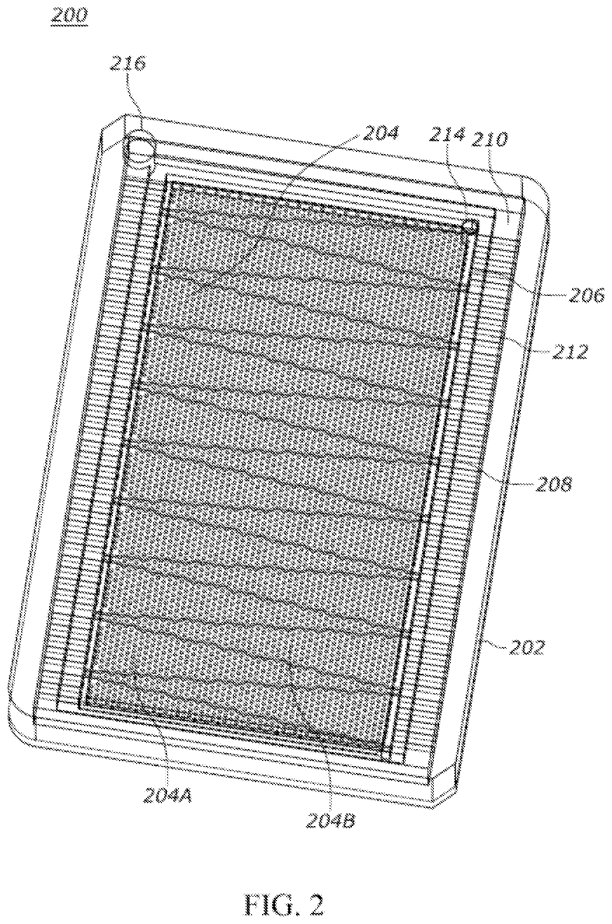

FIG. 2 illustrates a perspective view of a compliant counter-flow cold plate 200 according to embodiments of the present invention. FIG. 2 shows a transparent view in which internal details of the compliant counter-flow cold plate 200 are shown. The compliant counter-flow cold plate 200 includes a manifold body 202 having a number of expanding channels 204 formed therein. In the particular embodiment, illustrated in FIG. 2, the manifold body 202 includes sixteen expanding channels. In the embodiment illustrated in FIG. 2, the flow of fluid passing through adjacent expanding channels 204 are counter-flow with respect to one another. For example, a fluid flow through a first expanding channel 204A is in a counter direction to the flow through a second expanding channel 204B. The manifold body 202 includes an inlet channel 206 therein extending along each side of the manifold body 202 in a loop configuration and coupled to inlet orifices 208 of each of the expanding channels 204. In the particular embodiment illustrated in FIG. 2, each expanding channel 204 includes one inlet orifice 208.

The manifold body 202 further includes an outlet channel 210 therein extending along each side of the manifold body 202 in a loop-configuration and coupled to outlet orifices 212 of each of the expanding channels 204. In the particular embodiment illustrated in FIG. 2, each expanding channel 204 includes five slot-shaped outlet orifices 212. These multiple slot-shaped orifices assist in preventing manifold body distortion under internal pressure when compared with a design where the outlet orifice was not divided into sections. In an embodiment, the total cross-sectional area of the outlet orifices 212 of each expanding channel 204 is greater than the cross-sectional area of the inlet orifice 208 of the expanding channel 204 to accommodate volumetric expansion of the heat transfer liquid-vapor mix as it absorbs heat when passing through the expanding channel 204.

The manifold body 202 further includes a manifold inlet 214 coupled to the inlet channel 206 and a manifold outlet 216 coupled to the outlet channel 210. In a particular embodiment, the manifold body 202 is configured to be compliant under a distributed pressure load, for example, by a load plate coupled to the compliant counter-flow cold plate 200 by a compressible layer or other distributed pressure source. In a particular embodiment, the cross-sectional area of the manifold outlet 216 is greater than the cross-sectional area of the manifold inlet 214 to accommodate the volumetric expansion of the heat transfer fluid. Although not shown in FIG. 2, it should be understood that the manifold outlet 216 may be coupled to a heat dissipation device configured to receive the heat transfer fluid from the compliant counter-flow cold plate 200 and remove heat from the heat transfer fluid. The heat dissipation device may be further coupled to the manifold inlet 214 to return the cooled heat transfer fluid to the compliant counter-flow cold plate 200. In this embodiment a compressible layer may be disposed against the manifold body between the perimeter inlet and outlet manifold sections.

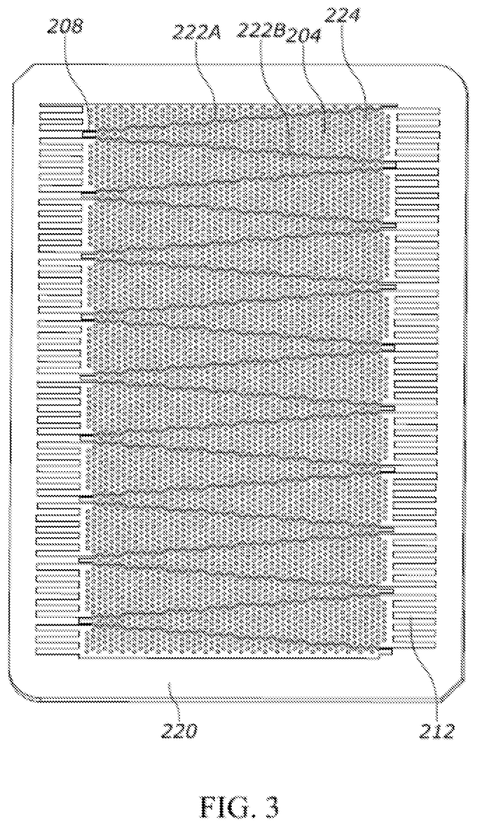

FIG. 3 illustrates another perspective view of the compliant counter-flow cold plate 200 of FIG. 2. FIG. 3 shows a lower portion 220 of the manifold body 202. As shown in FIG. 3, each expanding channel 204 includes a first sidewall 222A and a second sidewall 222B which diverge from one another as the expanding channel 204 extends from the inlet orifice 208 to the outlet orifices 212. The sidewalls serve to confine the individual channel's flow, keeping it separate from the flow in other channels. In the embodiment, each expanding channel includes a number of pin structures 224 within the channel to disrupt fluid flow through the channel and to provide increased heat transfer surface area.

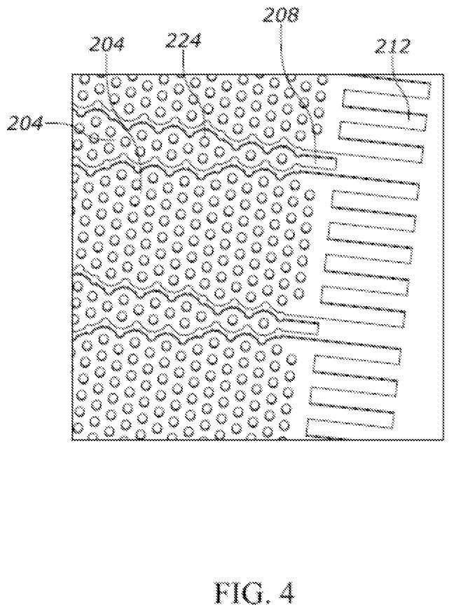

FIG. 4 shows a detail view of a portion of the expanding channels 204 of the compliant counter-flow cold plate 200 of FIG. 2. In the embodiment shown in FIG. 4, each of the first sidewall 222A and second sidewall 222B of the expanding channel 204 are formed in a zig-zag configuration extending from the inlet orifice 208 to the outlet orifices 212. In particular embodiments, the zig-zag configuration of the first sidewall 222A and the second sidewall 222B provide accommodation of the pin structures 224 and provide for increased structural rigidity to prevent deformation and/or failure of the expanding channels 204 when high pressure fluid is contained therein. FIG. 4 further illustrates a detail view of the pin structures 224 disposed within each of the expanding channels 204.

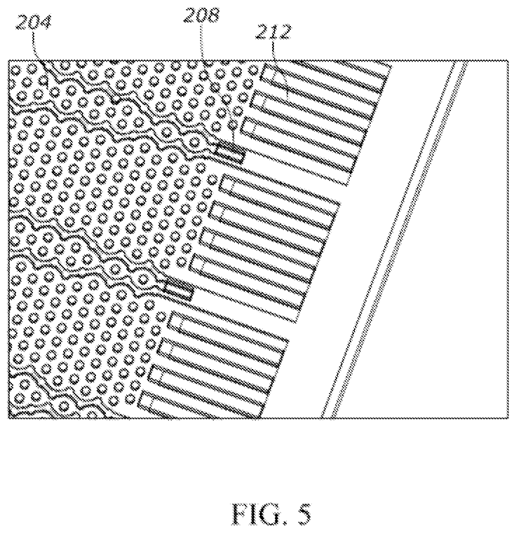

FIG. 5 shows a detail view of a portion of the compliant counter-flow cold plate 200 of FIG. 2. FIG. 5 shows a transparent view of a portion of the compliant counter-flow cold plate 200 including a particular expanding channel 204, an inlet orifice 208, and outlet orifices 212.

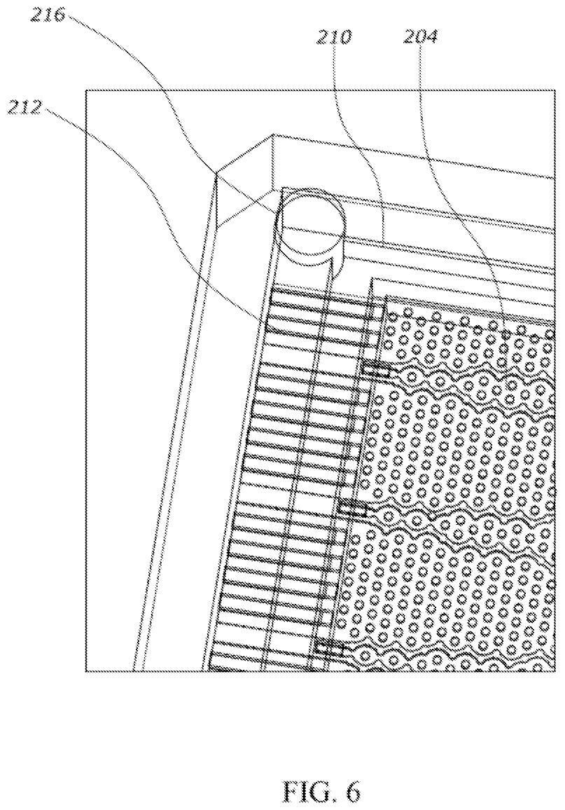

FIG. 6 shows a detail view of the manifold outlet 216 of the compliant counter-flow cold plate 200 of FIG. 2. FIG. 6 shows a transparent view of the manifold outlet 216 coupled to the outlet channel 210 of the manifold body 202. As shown in FIG. 6, the outlet channel 210 is further coupled to the output orifices 212 of the expanding channels 204.

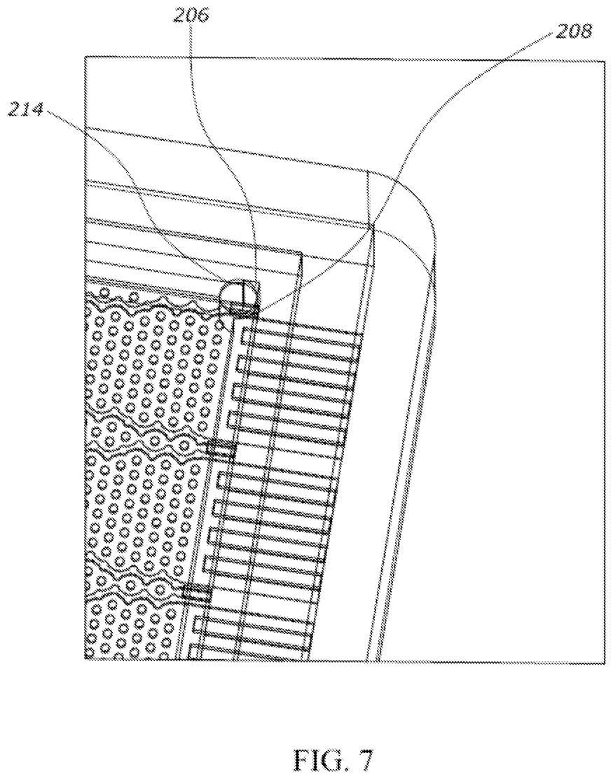

FIG. 7 shows a detail view of the manifold inlet 214 of the compliant counter-flow cold plate 200 of FIG. 2. FIG. 7 shows a transparent view of the manifold inlet 214 coupled to the inlet channel 206 of the manifold body 202. As shown in FIG. 7, the inlet channel 206 is further coupled to the input orifices 208 of the expanding channels 204.

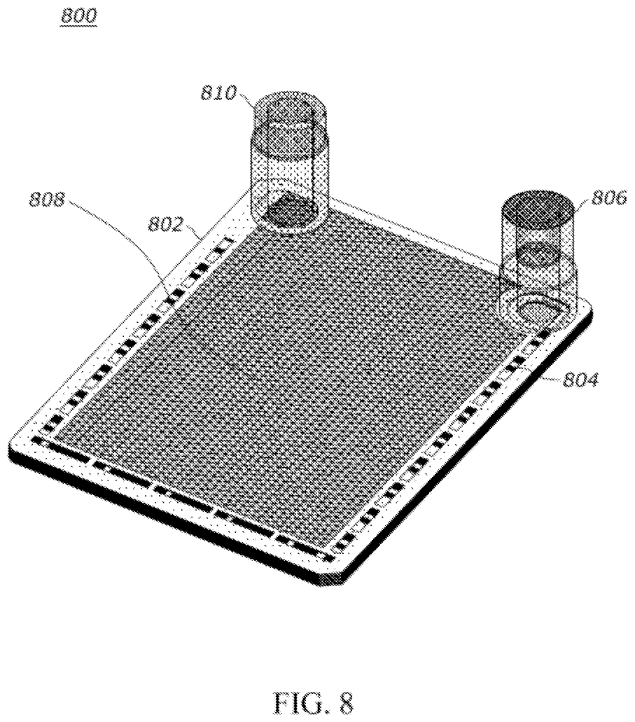

FIG. 8 illustrates a perspective view of a compliant counter-flow cold plate 800 according to another embodiment of the present invention. FIG. 8 shows a partial transparent view showing certain features of the counter-flow cold plate 800. The compliant counter-flow cold plate 800 includes a manifold body 802 formed of a number of stacked layers as will be further described herein. The manifold body 802 includes a number of counter-flow expanding channels (not shown) arranged in a manner similar as described with respect to the embodiment of FIG. 2. An inlet orifice of each of the expanding channels is coupled to an inlet channel/plenum 804. The inlet channel is further coupled to a manifold inlet (not shown) having an inlet fitting 806 attached thereto. In this embodiment, the outlet plenum is located centrally, with the inlet plenum 804 located peripherally. In an embodiment the outlet plenum is located more distal from the center of the cold plate than the inlet plenum.

In the embodiment illustrated in FIG. 8, a center portion of the manifold body forms a return plenum 808 coupled to outlet orifices (not shown) of each of the expanding channels as further described herein. Accordingly, the outlets of the expanding channels flow into the return plenum 808. In the embodiment illustrated in FIG. 8, substantially the entire central portion of manifold body 802 includes the return plenum 808. In particular embodiments, the return plenum 808 includes a matrix of heat dissipating structures arranged to allow fluid flow to pass through the matrix. These structures also serve to carry the load from the compressible layer down the expanding channel portions of the manifold body. The return plenum 808 is further coupled to a manifold outlet (not shown). The manifold outlet is further coupled to an outlet fitting 810.

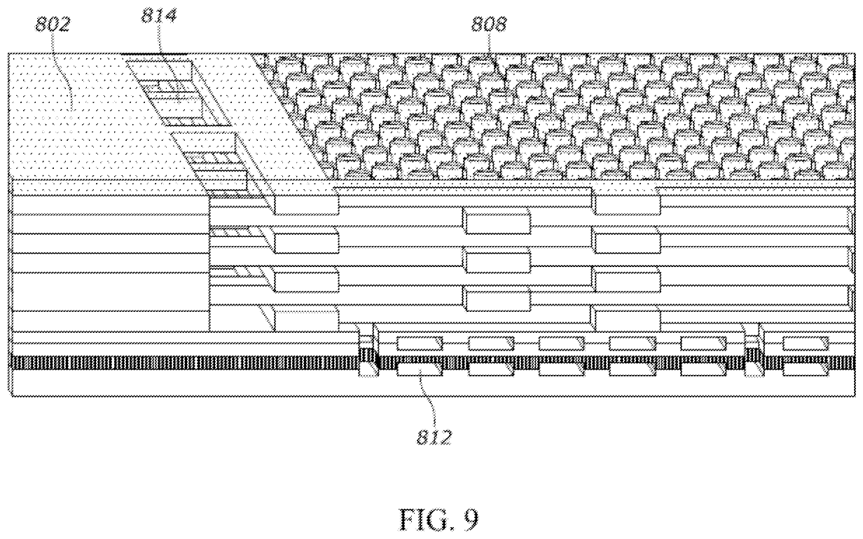

FIG. 9 illustrates a cut-away perspective side view of a portion of the compliant counter-flow cold plate 800 of FIG. 8. The embodiment illustrated in FIG. 9 shows the manifold body 802 being formed of twelve layers in a stacked configuration. A lower portion of the manifold body 802 shows a cut-away view of a portion of a number of expanding channel outlet sections 812 comparable to outlet orifices 212 and corresponding inlet channels 814. FIG. 9 further shows a detailed view of a portion of an output portion of the return plenum 808.

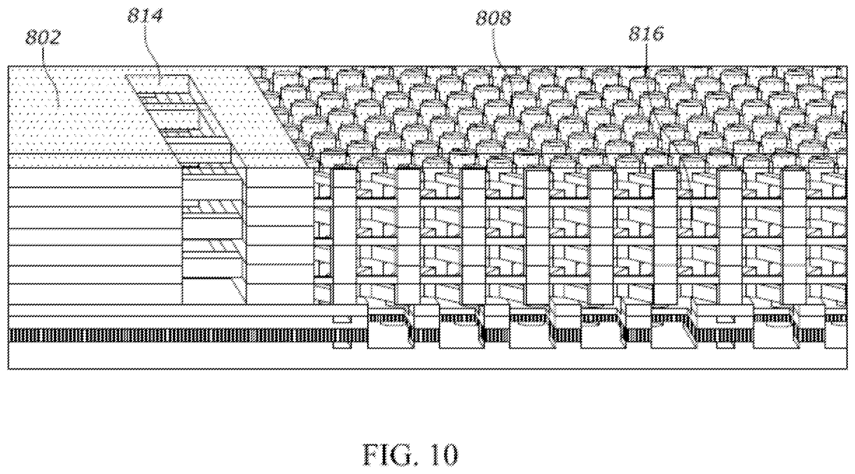

FIG. 10 illustrates another perspective cut-away side view of a portion of the compliant counter-flow cold plate 800 of FIG. 8. The embodiment of FIG. 10 shows the return plenum 808 being formed of a matrix of heat dissipating structures 816. In particular embodiments, the heat dissipating structures 816 provide for an increase in heat dissipation surface area.

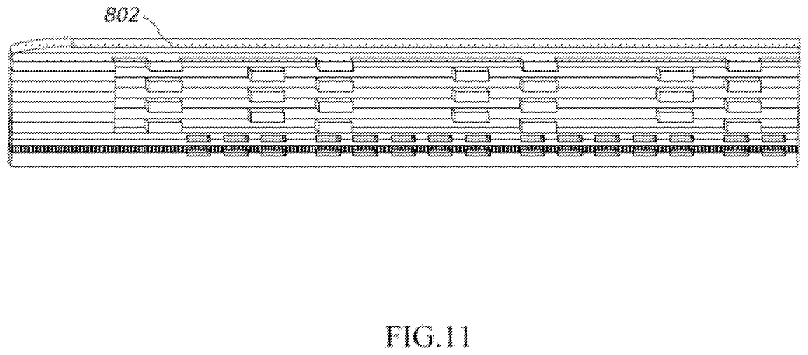

FIG. 11 illustrates a cut-away side view of a portion of the compliant counter-flow cold plate 800 of FIG. 8. FIG. 11 shows the plurality of layers forming the manifold body 802.

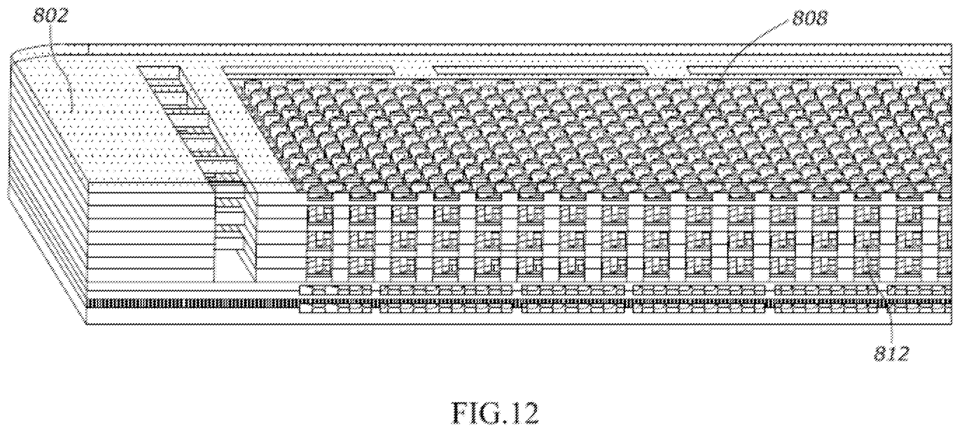

FIG. 12 illustrates another perspective cut-away side view of a portion of the compliant counter-flow cold plate 800 of FIG. 8. FIG. 12 shows the plurality of layers forming the manifold body 802 and the matrix of heat dissipating structures 816 of the return plenum 808.

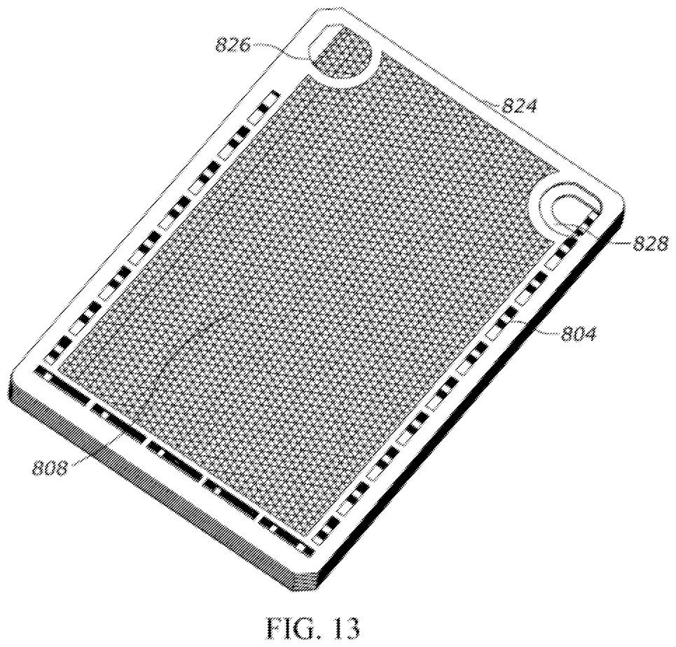

FIG. 13 illustrates a perspective view of a first layer 824 of the manifold body 802 of FIG. 8. The first layer 824 includes a portion of the return plenum 808, a manifold outlet 826, and a manifold inlet 828. As shown in FIG. 13, the manifold outlet 826 is disposed above and in fluid communication with the return plenum 808. The manifold inlet 828 is disposed above and in fluid communication with the inlet channel 804.

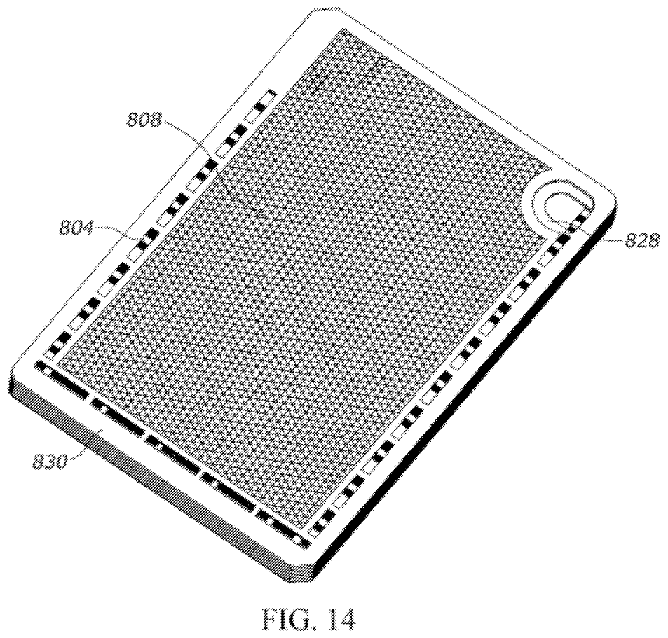

FIG. 14 illustrates a perspective view of a second layer 830 of the manifold body 802 of FIG. 8. The second layer 830 includes a portion of the return plenum 808 but no longer includes the manifold outlet 826. The manifold inlet 828 and inlet channel 804 are still included in the second layer 830.

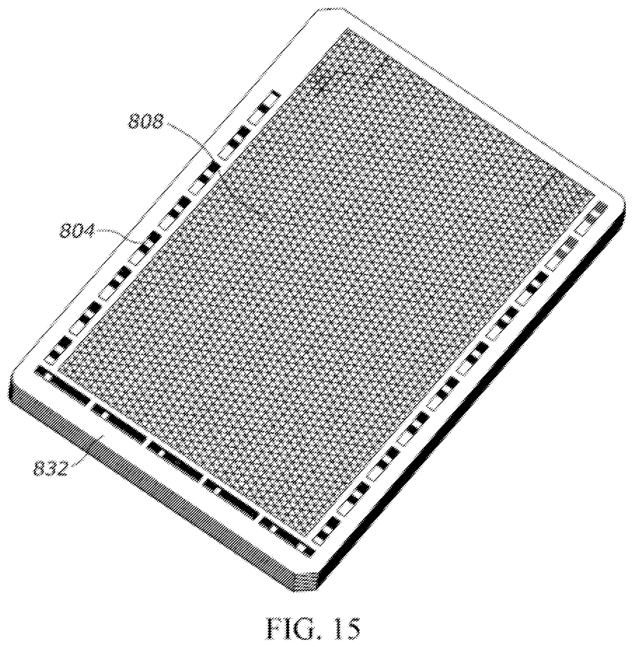

FIG. 15 illustrates a perspective view of a third layer 832 of the manifold body of FIG. 8. The third layer 832 includes a portion of the return plenum 808 but no longer includes the manifold outlet 826 or the manifold inlet 828. Some of the slots of the inlet channel 804 are still included in the third layer 832.

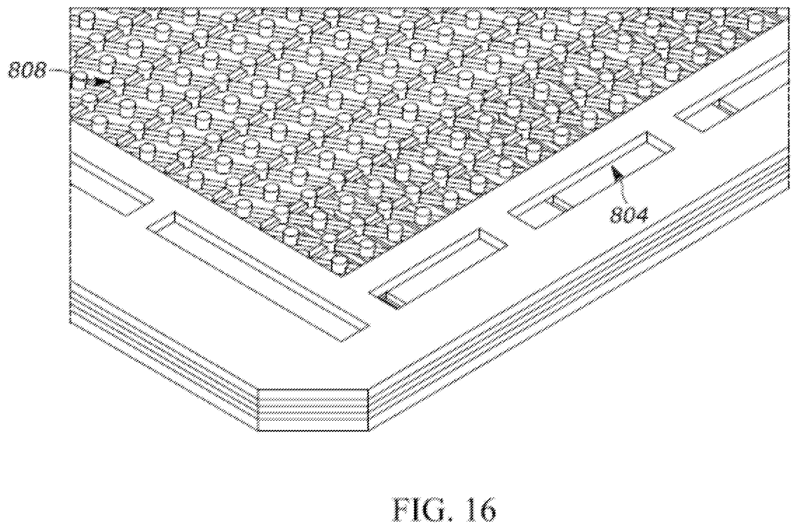

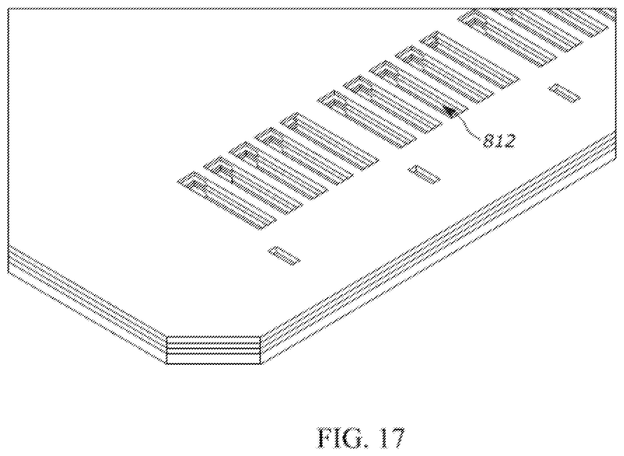

FIG. 16 illustrates another perspective view of the inlet and outlet structures for the centrally located return plenum of the manifold body of FIG. 8. In FIG. 16, a layer of the return plenum 808 and slots of the inlet channel 804 are shown. FIG. 17 illustrates still another perspective view of the inlet and outlet structures for the centrally located return plenum of the manifold body of FIG. 8. In FIG. 17, a portion of expanding channel outlet sections 812 are shown.

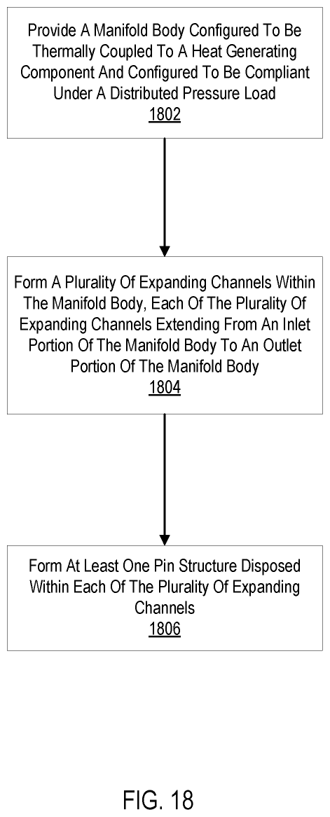

For further explanation, FIG. 18 sets forth a flow chart illustrating an exemplary method for compliant counter-flow cooling for a component according to embodiments of the present invention that includes providing 1802 a manifold body configured to be thermally coupled to a heat generating component. The method further includes forming 1804 a plurality of expanding channels within the manifold body. Each of the plurality of expanding channels extends from an inlet portion of the manifold body to an outlet portion of the manifold body. In a particular embodiment, a first cross-section area of each of the expanding channels is smaller at the inlet portion of the manifold body than a second cross-sectional area at the outlet portion of the manifold body.

In an embodiment, the method further includes forming 1806 at least one pin structure disposed within each of the plurality of expanding channels. In an embodiment, the plurality of expanding channels further includes a first expanding channel having a first flow direction and a second expanding channel having a second flow direction, the first flow direction being counter to the second flow direction. In an embodiment, the manifold body includes a return plenum in a center portion of the manifold body.

In view of the explanations set forth above, readers will recognize that the benefits of a compliant counter-flow cold plate for component cooling according to embodiments of the present invention include:
Improved performance and efficiency of cooling of heat generating components.
A compliant cold plate reduces stress on thermal interface materials between the cold plate and the heat generating component significantly improves performance due to a uniform gap and loading.
A cold plate having counter-flow expanding channels increases the efficiency of heat dissipation from heat generating components.
Expanding channels having sidewall portions arranged in a zig-zap pattern provide for guiding the fluid and separating the channels while maintaining the minimum etched feature width defined for the pin array.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. An apparatus for a compliant counter-flow cold plate for component cooling, comprising:
a manifold body configured to be thermally coupled to a heat generating component and configured to be compliant under a distributed pressure load; and
a plurality of expanding channels within the manifold body, at least one of the plurality of expanding channels extending from an inlet portion of the manifold body to an outlet portion of the manifold body.

2. The apparatus of claim 1, wherein a first cross-section area of the at least one of the plurality of expanding channels is smaller at the inlet portion of the manifold body than a second cross-sectional area at the outlet portion of the manifold body.

3. The apparatus of claim 1, further comprising at least one pin structure disposed within the at least one of the plurality of expanding channels.

4. The apparatus of claim 1, wherein the plurality of expanding channels further includes a first expanding channel having a first flow direction and a second expanding channel having a second flow direction, the first flow direction being counter to the second flow direction.

5. The apparatus of claim 1, wherein the outlet portion of the manifold body includes a return plenum in a center portion of the manifold body.

6. The apparatus of claim 5, wherein the return plenum includes a matrix of heat dissipating structures.

7. The apparatus of claim 5, wherein the return plenum includes a matrix of load carrying structures.

8. The apparatus of claim 5, wherein the outlet portion of the manifold body further includes a manifold outlet coupled to the return plenum.

9. The apparatus of claim 1, wherein the at least one of the plurality of expanding channels includes at least two sidewall portions arranged in a zig-zag configuration.

10. The apparatus of claim 1, wherein the manifold body includes a first manifold body portion coupled to a second manifold body portion.

11. The apparatus of claim 1, wherein the manifold body is formed of a plurality of stacked layers.

12. The apparatus of claim 1, wherein the inlet portion comprises an inlet channel coupled to an inlet orifice of the at least one of the plurality of expanding channels.

13. The apparatus of claim 12, wherein the inlet channel is arranged in a loop configuration within the manifold body.

14. The apparatus of claim 1, wherein the outlet portion comprises an outlet channel coupled to one or more outlet orifices of each of the plurality of expanding channels.

15. The apparatus of claim 14, wherein the outlet channel is arranged in a loop configuration within the manifold body.

16. An apparatus for a compliant counter-flow cold plate for component cooling, comprising:
a manifold body configured to be thermally coupled to a heat generating component; and
a plurality of expanding channels within the manifold body, at least one of the plurality of expanding channels extending from an inlet portion of the manifold body to an outlet portion of the manifold body;
at least one pin structure disposed within the at least one of the plurality of expanding channels; and
wherein the plurality of expanding channels further includes a first expanding channel having a first flow direction and a second expanding channel having a second flow direction, the first flow direction being counter to the second flow direction.

17. The apparatus of claim 16, wherein a first cross-section area of the at least one expanding channel is smaller at the inlet portion of the manifold body than a second cross-sectional area at the outlet portion of the manifold body.

18. A method for compliant counter-flow cooling for a component comprising:
providing a manifold body configured to be thermally coupled to a heat generating component and configured to be compliant under a distributed pressure load; and
forming a plurality of expanding channels within the manifold body, at least one of the plurality of expanding channels extending from an inlet portion of the manifold body to an outlet portion of the manifold body.

19. The method of claim 18, wherein a first cross-section area of the at least one of the plurality of expanding channels is smaller at the inlet portion of the manifold body than a second cross-sectional area at the outlet portion of the manifold body.

20. The method of claim 18, further comprising forming at least one pin structure disposed within the at least one of the plurality of expanding channels.
